(19) United States
(12) Patent Application Publication
(10) Pub. No.: US 2022/0393431 A1
(43) Pub. Date: Dec. 8, 2022

(54) MONOLITHIC MICRO-PILLAR PHOTONIC CAVITIES BASED ON III-NITRIDE SEMICONDUCTORS

(71) Applicant: U.S. Army DEVCOM Army Research Laboratory, Adelphi, MD (US)

(72) Inventors: Michael D. Gerhold, Raleigh, NC (US); Alexander Franke, Raleigh, NC (US); Zlatko Sitar, Apex, NC (US); Ramon Collazo, Raleigh, NC (US); Ronny Kirste, Durham, NC (US); Dorian Alden, Raleigh, NC (US)

(21) Appl. No.: 17/832,769

(22) Filed: Jun. 6, 2022

Related U.S. Application Data
(60) Provisional application No. 63/208,146, filed on Jun. 8, 2021.

(51) Int. Cl. H01S 5/125; C30B 25/04; C30B 25/18; C30B 29/40; C30B 33/10

(52) U.S. Cl. CPC H01S 5/125; C30B 25/04; C30B 25/186; C30B 29/403; C30B 33/10

(57) ABSTRACT

A method of making a Group III nitride material that includes: providing a substrate; patterning a template on the substrate; depositing a layer of a material comprising aluminum, gallium and nitrogen on the substrate at a temperature; annealing the layer comprising aluminum, gallium and nitrogen; epitaxially growing Distributed Bragg Reflectors to form a structure on the substrate that comprises microcavities; and etching micropillars in the structure for at least 30 seconds with a heated basic solution is described.

### CROSS REFERENCE TO RELATED APPLICATION

This application claims the benefit of U.S. Provisional Patent Application No. 63/208,146 filed on Jun. 6, 2021, the contents of which, in its entirety, is herein incorporated by reference.

### GOVERNMENT INTEREST

This invention was at least partially funded by the United States Army Research Laboratory under Cooperative Agreement W911NF-15-2-0068. Thus, embodiments herein may be manufactured, used, and/or licensed by or for the United States Government without the payment of royalties thereon.

### BACKGROUND

### Technical Field

The embodiments herein generally relate to compositions of matter, and more particularly to III-nitride semiconductors and methods of making III-nitride semiconductors.

### Description of the Related Art

U.S. Pat. No. 7,815,970 titled “Controlled polarity group III-nitride films and methods of preparing such films” by one of the present inventors, Zlatko Sitar, and other researchers describes methods of preparing Group III-nitride films.

U.S. Pat. No. 8,734,965 titled “Controlled polarity group III-nitride films and methods of preparing such films” by present inventor, Zlatko Sitar and Ramon Collazo, and others also describes methods of preparing Group III-nitride films.

A journal article titled “Properties of AlN based lateral structures” Phys. Status Solidi C, 1-4 (2014) by present inventors, Ronny Kirste, Michael Gerhold, Ramon Collazo and Zlatko Sitar, and others describes growth and characterization of AlN based polarity structures.

Other U.S. Patents and Patent Application Publications that may be of interest include: U.S. Pat. No. 9,840,790 titled “Highly transparent aluminum nitride single crystalline layers and devices made therefrom” to present inventor Zlatko Sitar, and others; U.S. Patent Application Publication no. 2017/0154963 titled “CONTROLLED DOPING FROM LOW TO HIGH LEVELS IN WIDE BANDGAP SEMICONDUCTORS” to present inventors Zlatko Sitar and Ramon Collazo, and others; U.S. Patent Application Publication no. 2015/0247260 titled “HIGHLY TRANSPARENT ALUMINUM NITRIDE SINGLE CRYSTALLINE LAYERS AND DEVICES MADE THEREFROM” to present inventor Zlatko Sitar and Ramon Collazo and others; U.S. Pat. No. 8,822,045 titled “Passivation of aluminum nitride substrates” to present inventors Zlatko Sitar and Ramon Collazo, and other; U.S. Patent Application Publication no. 2012/0168772 titled “PASSIVATION OF ALUMINUM NITRIDE SUBSTRATES” to present inventor Zlatko Sitar and Ramon Collazo and other; U.S. Pat. No. 8,148,802 titled “Passivation of aluminum nitride substrates” to present inventor Zlatko Sitar and Ramon Collazo and other; U.S. Patent Application Publication no. 2011/0140124 titled “PASSIVATION OF ALUMINUM NITRIDE SUBSTRATES” to present inventor Zlatko Sitar and Ramon Collazo and other; U.S. Pat. No. 7,915,178 titled “Passivation of aluminum nitride substrates” to present inventors Zlatko Sitar and Ramon Collazo and other; U.S. Patent Application Publication no. 2011/0020602 titled “CONTROLLED POLARITY GROUP III-NITRIDE FILMS AND METHODS OF PREPARING SUCH FILMS” to present inventor Zlatko Sitar and others; U.S. Pat. No. 7,678,195 titled “Seeded growth process for preparing aluminum nitride single crystals” to present inventor Zlatko Sitar and others; U.S. Patent Application Publication no. 2010/0025823 titled “PASSIVATION OF ALUMINUM NITRIDE SUBSTRATES” to present inventor Zlatko Sitar and Ramon Collazo and other; U.S. Patent Application Publication no. 2070/0257333 titled “Seeded growth process for preparing aluminum nitride single crystals” to present inventor Zlatko Sitar and others; U.S. Patent Application Publication no. 2006/0257626 titled “CONTROLLED POLARITY GROUP III-NITRIDE FILMS AND METHODS OF PREPARING SUCH FILMS” to present inventor Zlatko Sitar and Ramon Collazo and other; and U.S. Patent Application Publication no. 2011/0166045 titled “WAFER SCALE PLASMONICS-ACTIVE METALLIC NANOSTRUCTURES AND METHODS OF FABRICATING SAME” to present inventor Michael Gerhold and others.

The above U.S. Patents and journal article and any other patents and journal articles mentioned herein are hereby incorporated by reference herein in their entireties.

### SUMMARY

In view of the foregoing, an embodiment herein provides a method of making a III nitride material that includes: providing a substrate; patterning a template on the substrate; depositing a layer of a material comprising aluminum, gallium and nitrogen on the substrate; epitaxially growing Distributed Bragg Reflectors to form a structure on the substrate that comprises microcavities; and etching micropillars in the structure. In certain embodiments the aluminum, gallium and nitrogen layer is deposited on the substrate at a temperature between 450° C. and 850° C., In other embodiments the aluminum, gallium and nitrogen layer is deposited on the substrate at a temperature between 500° C. and 800° C. In still other embodiments the aluminum, gallium and nitrogen layer is deposited on the substrate at a temperature between 600° C. and 700° C. And in yet other embodiments the aluminum, gallium and nitrogen layer is deposited on the substrate at a temperature greater than 900° C. In some embodiments, the layer comprising aluminum, gallium and nitrogen is annealed at a temperature greater than 950° C. In other embodiments, the layer comprising aluminum, gallium and nitrogen is annealed at a temperature greater than 1000° C. In some embodiments, the etching is done with a basic solution heated to a temperature greater than 45° C. In other embodiments, the etching is done with a basic solution heated to a temperature greater than 50° C. In still other embodiments, the etching is done with a basic solution heated to a temperature greater than 55° C. The etching may be for at least 30 seconds, for at least 45 seconds, for at least 50 seconds, for at least 60 seconds or even for at least 90 seconds.

The present invention also provides a method of making a III nitride material that includes: providing a substrate; patterning a template on the substrate; depositing a layer of a material comprising aluminum, gallium and nitrogen on the substrate at a temperature between 450° C. and 850° C.; annealing the layer comprising aluminum, gallium and nitrogen at a temperature greater than 900° C.; epitaxially growing Distributed Bragg Reflectors to form a structure on the substrate that comprises microcavities; and etching micropillars in the structure for at least 30 seconds with a basic solution heated to a temperature of at least 45° C.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 is a schematic representation of the micro-pillar microcavity fabrication process. Details on the fabrication for the example of an AlN/Al0.65Ga0.35N (Distributed Bragg Reflector) DBR based microcavity are included in the process flow description;

FIG. 2 illustrates etching time adjustment to achieve DBR structures. By exposing the as grown structure (left top) to KOH solution, the nitrogen/mixed polar material is etched leaving the free-standing micro-pillar DBR structures;

FIG. 3 illustrates surface morphology at different microscope magnifications before and after KOH etching;

FIG. 4 is a graph showing reflectivity spectra of 28.5×DBR on patterned AlN/sapphire substrate before (black—wafer center, red—wafer edge) and after KOH etching. This optical data is based on the example described in the procedure section. Lower reflectivity than on a single epitaxial DBR structure is observed, as our measuring spot size is much larger than the micro-pillar device. Nevertheless, 28.5 pairs have not been previously achieved on such a planar structure without cracking; and

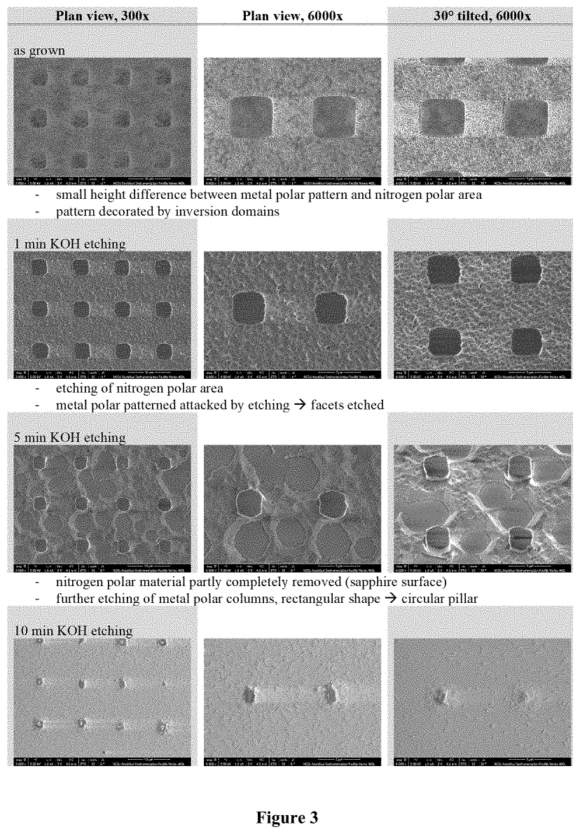

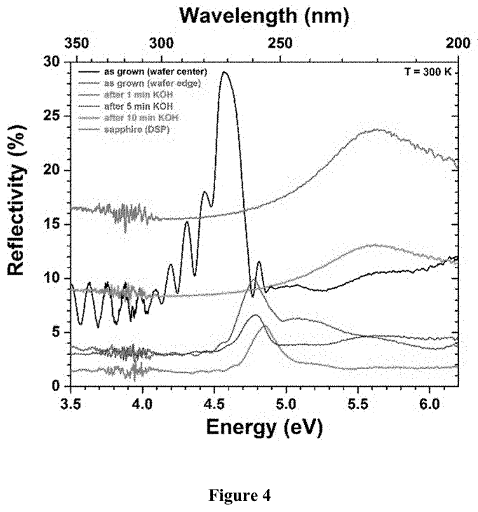

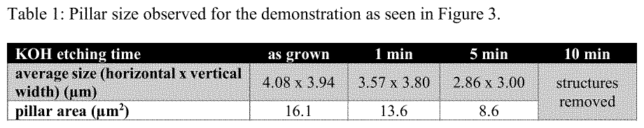

TABLE 1 presents pillar size observed for the demonstration as seen in FIG. 3.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

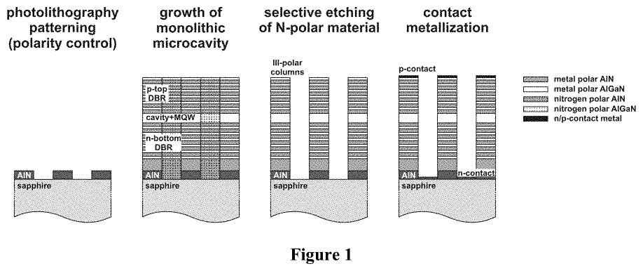

The embodiments herein provide new methods of making Group III Nitride materials that useful for lasers and other semiconductor and electronic applications. Referring now to the drawings, and more particularly to FIGS. 1 through 4 and Table 1, there are shown exemplary embodiments.

Group III-nitride semiconductor microcavities allow for the development of novel applications based on different ways in which light and matter couples. Drastic changes in the light output characteristic from these cavities are achieved by surrounding an active emitter, such as a quantum well structure, by the two mirrors of a Fabry-Perot resonator. A weak coupling of quantum well excitons, Coulomb attracted correlated electron-hole pairs, with a cavity mode of the resonator results in an enhancement of spontaneous emission rate (Purcell effect) and directional emission at the resonance energy of both modes. This leads to the typical lasing mode encountered in normal operation of devices such as vertical cavity surface emitting lasers (VCSEL) or in its external (VECSEL) configuration. In contrast, two admixed polaritonic emission modes (coupling between photon and exciton) showing an anticrossing angle dispersion behavior arise in the strong coupling regime. Because of their bosonic nature and strongly reduced effective mass, fundamental properties like Bose-Einstein condensation, as well as polaritonic devices such as polariton lasers can be realized. These lasers do not need population inversion and ultra-low thresholds are achievable at remarkable high temperatures. Thus, development of these microcavities allows for the further development of advanced laser structures such as the VCSELs and leads to the realization of such breakthroughs as polariton lasers.

The III-nitrides have been identified as a material system with great promise to realize these observations. This material system offers an increased coupling strength of the light matter interaction and provides stable polaritons above room temperature, thanks to their high exciton binding energy. Nevertheless, significant material technological advances are needed to realize such a laser in the visible to deep UV spectral range. These require the integration of epitaxial Distributed Bragg Reflectors (DBRs) with dielectric-based DBRs to form the microcavity or the complete monolithic integration with epitaxial DBRs. The integration is limited to the deposition of epitaxial thin-films and then the dielectrics with the corresponding formation of deleterious defects within the DBRs. Thus, the applicability of these DBRs for the formation of these microcavities is limited to a maximum thickness due to accumulated strain energy within the thin films that leads to cracking and therefore a lower reflectivity. By implementing methods based on the fabrication of lateral polar structures, this limitation is avoided, thus thick DBRs can be realized for top and bottom reflectors for a variety of III-nitride semiconductors and wavelengths of interest.

The photonic microcavity is achieved by bringing two DBRs together with reflectivity exceeding ideally 99.99%. These DBRs are positioned above and below the active region, where gain is achieved. The reflectivity in these DBRs is determined by alternating pairs of optically transparent materials at a specific thickness with a designed contrast in refractive index. As a specific example, pairs of AlN/AlGaN epitaxial films are grown for DBRs in the deep UV regime (˜270 nm). Sufficiently thick films of alternating pairs are needed to achieve the necessary reflectivity, thus the total thickness needs to be below the critical thickness for cracking. Typical critical thickness for the structure described is around 1.5 μm or 26 pairs, corresponding to a reflectivity of around 98%. Cracking typically occurs even before completing the first DBR for optimum reflectivity, thus the need of using dielectric DBRs that are either deposited or wafer bonded to the active/bottom DBR structure.

In this invention, we demonstrate the possibility of growing a thick monolithic, all epitaxial microcavity structure based on III-nitrides. Following this, it will allow for a high-quality factor (Q-factor) exceeding 105 throughout all the wavelengths of interest. The following advantages are expected from such a structure:
1. high crystalline and optical quality in the active region;
2. a near symmetric structure for improved field distribution;
3. controllable doping of the complete structure is possible; and
4. it is based on established processing procedures for nitrides on sapphire substrates; and
5. as a monolithic porces, instead of two steps for hybrid microcavity it reduced any possible detrimental effects on the active region.

In addition to these advantages, the process facilitates the formation of microcavities in the form of micro-pillars. This provides for an additional lateral confinement of the light field besides the vertical confinement expected from the DBRs. Thus allowing for a further reduction of the lasing threshold. The process described in the next section provides for an easy and efficient way of obtaining these micro-pillars, as only a basic solution based on KOH is needed to define the mesa (pillar) region. This is based on an established procedure as described in previous patents from our group. No further processing steps are required to define the mesa after its growth, thus allowing for a simple device fabrication procedure.

The following procedure describes the basics for the fabrication of these micro-pillar microcavities. FIG. 1 shows the procedure in a schematic form. In the following, it is described in the form as a process flow outline. Specifically, FIG. 1 illustrates a schematic representation of the micro-pillar microcavity fabrication process. Details on the fabrication, for the example of an AlN/Al_{0.65} Ga_{0.35}N DBR based microcavity are included in the process flow description, where the layers include a metal polar AlN layer (gray shaded areas), a metal polar AlGaN layer (unshaded areas), nitrogen polar AlN layer (dotted and gray shaded areas), nitrogen polar AlGaN layer (dotted unshaded areas) and n/p contact metal (darkest shaded areas).

The fabrication procedure includes

1. Growth and patterning of a template (buffer/nucleation) layer

a. deposition of 17 nm thick AlN layer at 650° C. on sapphire substrate and post annealing at 1040° C.

b. pre-patterning of template by standard photolithography (mask aligner/UV exposure—developing—Acetone/Methanol/DI Water cleaning—O2 plasma (Asher))

2. Epitaxial growth of the DBR/microcavity structure

a. 300 nm thick A1N template (1150° C.≤T≤1250° C.; low MN ratio around 100; Trimethylaluminum, Ammonia as metal and nitrogen precursor)

b. Growth of the desired number of layer pairs, e.g. AlN/Al0.65Ga0.35N DBR
i. single layer thickness: λ/4n (λ: resonance wavelength, n: refractive index of nitride material; T˜1075° C.; Trimethylaluminum,nTriethylgallium, Ammonia as metal and nitrogen precursor)
   3. Wet etching to define micro pillars

a. Potassium hydroxide KOH solution (1 mol) heated to 60° C.—etching time

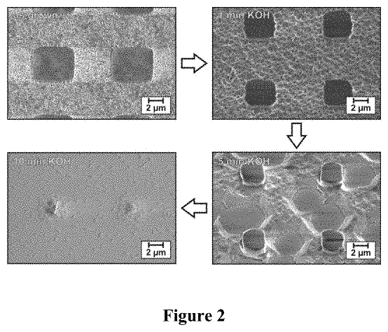

FIG. 2 shows an example of the necessary etching time adjustment and the corresponding results obtained for the microcavities. An optimum time is expected to be 1 minute for the conditions used in the exampled described in this disclosure. FIG. 2 illustrates how etching time adjustment to achieve DBR structures. By exposing the as grown structure (left top) to KOH solution, the nitrogen/mixed polar material is etched leaving the free-standing micro-pillar DBR structures. FIG. 3 shows in details the expected micro-pillars at different microscope magnifications and etching times. Included are some comments for processing description.

In summary, the procedure is based on the observation that AlGaN grows relaxed when grown using the lateral polar structure procedure as described in other references and patents. Using such a procedure simplifies the process such that the listed advantages for such micro-pillar microcavity could be achieved.

FIG. 3 shows surface morphology at different microscope magnifications before and after KOH etching from left to right in plan view at 330×, in plan view at 6000× and at 30° tilted at 6000× and from top to bottom: (1) as grown structures illustrating small height differences between metal polar pattern and nitrogen polar area and patter decorated by inversion domains; (2) structures after 1 minute of KOH etching illustrating etching of nitrogen polar area metal polar patterned attacked by etching showing facets etched; (3) structures after 5 minutes of KOH etching illustrating nitrogen polar material partly completely removed (sapphire surface) and further etching of metal polar columns, rectangular shape to circular pillar; and (4) structures after 10 minutes of KOH etching illustrating complete removal of metal and nitrogen polar material.

TABLE 1 presents pillar size observed for the examples seen in FIG. 3. An average size (horizontal×vertical width) 4.08 μm×3.94 μm and pillar area of 16.1 μm² was measured for the as grown structures in FIG. 3. An average size (horizontal×vertical width) 3.57 μm×3.80 μm and pillar area of 13.6 μm² was measured for the as after 1 minute of KOH etching in FIG. 3. An average size (horizontal×vertical width) 2.86 μm×3.30 μm and pillar area of 8.6 μm² was measured for the structures after 5 minutes of KOH etching in FIG. 3. And, now measurements were made for the structures etched for 10 minutes as the structures were removed by the etching.

FIG. 4 presents reflectivity spectra of 28.5×DBR on patterned AlN/sapphire substrate before (black—wafer center, red—wafer edge) and after KOH etching at 300° K for examples from top to bottom at far right of graph at about 6.2 eV: sapphire (DSP) pink line, as grown (wafer center) black line, after 10 min KOH teal line, after 5 min KOH dark blue line, as grown (wafer edge) red line) and after 1 min KOH green line. This optical data is based on the example described in the procedure section. Lower reflectivity than on a single epitaxial DBR structure is observed, as our measuring spot size is much larger than the micro-pillar device. Nevertheless, 28.5 pairs have not been previously achieved on such a planar structure without cracking. FIG. 4 presents the reflectivity spectra for: as grown (wafer center) black line with highest reflectivity peak at about 29% and about 4.6 eV; as grown (wafer edge) red line with highest reflectivity peak at about 24% and about 5.6 eV; structure after 1 minute KOH green line with highest reflectivity peak at about 5% and about 4.9 eV; structure after 5 minute KOH dark blue line with highest reflectivity peak at about 6% and about 4.8 eV; structure after 10 minute KOH teal or light blue line with highest reflectivity peak at about 13% and about 5.6 eV; and as sapphire (DSP) pink line with highest peak at about 24% and about 5.6 eV.

Following the example described in the previous section, certain characteristics to demonstrate feasibility will be discussed. FIG. 4 shows the reflectivity spectra for a 28.5 pair single DBR micro-pillar microcavity after processing. No cracking was observed for the complete epitaxial structure. A stop band at 270.3 nm (4.59 eV) was observed for this micro-pillar structure and a similar planar thin film structure, suggesting a similar reproducibility for the micro-pillar structure to that of the planar sample. There was a pronounced absorption at the band edge of the Al_{0.65} Ga_{0.35}N, thus the reflectivity drop at the shorter wavelengths and the stop band edges softens. The observed increase in reflectivity with KOH etching time shown in FIG. 4 is to be considered an artifact, as there is increase contribution from the sapphire surface with much lower diffuse scattering. Further work will focus in obtaining microscopic measurements of the micro-pillar response, i.e. reflectivity and luminescence, as these are not affected by the measurement artifact previously described.

A complete monolithic microcavity based on these micro-pillar structures should be achievable based on the process described in the previous section. The simultaneous growth of both polar orientations of the III-nitride material and their corresponding etching selectivity allows for strain free structures that would be of sufficient thickness for a complete microcavity. Difficulty in extending the concept of microcavities to the deep-UV has led to slow progress in the demonstration of lasing in that wavelength range. This is because of problems with strain management as previously discussed. Such a structure (micro-pillar) and process will make feasible the possibility of demonstrating VCSEL and other cavity based optoelectronic devices. In addition, this process could be extended to other materials that are non-centrosymmetric, such as ZnO. The process uses the possibility of obtaining different patterned polar domains within a single substrate and exploiting the typically observed chemical selectivity between the two domains. In this way, strain is not only managed but fabrication of the micro-pillar is easily obtained in a top-down approach.

The microcavity described above can be used in similar form in a number of optoelectronic devices. VCSELs (Vertical Cavity Surface Emitting Lasers), VCSOAs (Vertical Cavity Semiconductor Optical Amplifiers), and polariton lasers (high quality factor microcavity providing strong photon-matter coupling) are examples. One important aspect to such optoelectronic devices is whether they can be optically or electrically controlled (or both). Electrical control, known as electrical injection, means that the devices can be turned on and off with and electrical bias voltage. Optical control, known as optical pumping, means that electromagnetic waves (optical, electron beam, . . . ) are used to turn the device on and off and control its output power level. Either way, microcavities similar to the ones described would be incorporated. With electrical injection though, doped semiconductor with n-type and p-type layers placed in the appropriate part of the cavity would be used to inject carriers that would recombine to emit photons in what is known as the “active region” of the device. Optically pumped devices generate carriers which also recombine in the active region but the optical signal is imparted from an external source. Electrical contacts would need to be made to both the n and p-type epilayers for a voltage to be applied and a current to flow. Such n type and p-type devices for p-n junction diodes, known and used for many decades. Integrated circuit technology is based on such prior knowledge.

The advantage of the microcavity growth technique is that it could lead to vertical cavity surface emitting lasers (VCSELs) and polariton lasers at shorter ultraviolet (UV) wavelengths. Presently known devices only lase above 336 nm, in the commercially available device market. A few publications have shown wavelengths less than that but none has shown itself to be viable for commercialization as of yet. Prior art utilizes AlGaN heterostructures with much less aluminum. Such AlGaN alloys emit at longer wavelengths that are much less useful for important military and commercial applications (see below).

The problem thus far has been the inability to create high enough reflectivity mirrors. For distributed Bragg reflectors (known as DBRs), the reflectivity is proportional to the refractive index contrast and number of quarter wavelength layers. Thus far, the DBRs have not been grown thick enough to achieve a high reflectivity, e.g. after a certain critical thickness the mirrors will crack and not be of use. In certain embodiments, the present invention provides thicker crackfree epilayers achieved with such templates could be used for microcavities. The templating method was tried, and success was found.

Potential uses of the present invention include the development of ultraviolet light vertical cavity surface emitting lasers (aka VCSELs) including the possibility of forming polariton lasers (with high enough quality factors used to create the strong coupling needed to form polaritons. Polaritons are light-matter quasi-particles that behave similar to photons (bosonic nature) and can potentially form Bose-Einstein condensates that become coherent at a threshold of 3-4 orders of magnitude less density than that needed in standard photon lasers.) UV VCSELs and UV polariton lasers are useful for a number of potential applications. Examples include optical data storage, optical interconnects—data communications, chemical or biomolecule sensors, water purification, surface sterilization, free-space optical communication, modifiying and/or enhancing plant growth, and possibly others.

VCSELs and polariton lasers have not been demonstrated for the most part in the UV below 350 nm, and certainly not below 336 nm. The invention here is applicable to alloy of AlGaN which may produce VCSELs from around 200 nm up to 360 nm depending on the mirror design. Polariton lasers are a similar device to a VCSEL with much higher quality factors. Polariton lasing has the potential to be orders of magnitude more energy efficient than standard photon lasers. Also, the dynamics of lasing in terms of modulation bandwidth have not been adequately explored to know what their potential would be, but it may exceed those of VCSELs.

III-nitrides have been identified as a material system with great promise to realize microcavities to exploit photon-exciton coupling for technologically important novel optoelectronic devices. This material system offers an increased coupling strength of the light matter interaction by providing stable polaritons above room temperature. These microcavities require the integration of epitaxial Distributed Bragg Reflectors (DBRs) with dielectric-based DBRs to form the microcavity or the complete monolithic integration with epitaxial DBRs. Nevertheless, the applicability of these DBRs for the formation of these microcavities is limited to a maximum thickness due to accumulated strain energy within the thin films that leads to cracking and therefore a lower reflectivity. By implementing methods based on the fabrication of lateral polar structures, this limitation is avoided, thus thick DBRs can be realized for top and bottom reflectors to build a complete monolithic microcavities for a variety of III-nitride semiconductors and wavelengths of interest.

The foregoing description of the specific embodiments will so fully reveal the general nature of the embodiments herein that others may, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein may be practiced with modification within the spirit and scope of the appended claims.

What is claimed is:

1. A method of making a III nitride material, the method comprising:
providing a substrate;
patterning a template on the substrate;
depositing a layer of a material comprising aluminum, gallium and nitrogen on the substrate;
epitaxially growing Distributed Bragg Reflectors to form a structure on the substrate that comprises microcavities; and
etching micropillars in the structure.

2. The method of claim 1 wherein depositing the layer comprising aluminum, gallium and nitrogen on the substrate occurs between 450° C. and 850° C.

3. The method of claim 1 wherein depositing the layer comprising aluminum, gallium and nitrogen on the substrate occurs between 500° C. and 800° C.

4. The method of claim 1 wherein the layer comprising aluminum, gallium and nitrogen on the substrate is annealed between 600° C. and 700° C.

5. The method of claim 2 wherein the layer comprising aluminum, gallium and nitrogen is annealed at a temperature greater than 900° C.

6. The method of claim 2 wherein the layer comprising aluminum, gallium and nitrogen is annealed at a temperature greater than 950° C.

7. The method of claim 2 wherein the layer comprising aluminum, gallium and nitrogen is annealed at a temperature greater than 1000° C.

8. The method of claim 1 wherein etching is done with a basic solution heated to a temperature greater than 45° C.

9. The method of claim 1 wherein etching is done with a basic solution heated to a temperature greater than 50° C.

10. The method of claim 1 wherein etching is done with a basic solution heated to a temperature greater than 55° C.

11. The method of claim 8 wherein the etching is for at least 30 seconds.

12. The method of claim 8 wherein the etching is for at least 45 seconds.

13. The method of claim 8 wherein the etching is for at least 50 seconds.

14. The method of claim 8 wherein the etching is for at least 60 seconds.

15. The method of claim 8 wherein the etching is for at least 90 seconds.

16. A method of making a III nitride material, the method comprising:
providing a substrate;
patterning a template on the substrate;
depositing a layer of a material comprising aluminum, gallium and nitrogen on the substrate at a temperature between 450° C. and 850° C.;
annealing the layer comprising aluminum, gallium and nitrogen at a temperature greater than 900° C.;
epitaxially growing Distributed Bragg Reflectors to form a structure on the substrate that comprises microcavities; and
etching micropillars in the structure for at least 30 seconds with a basic solution heated to a temperature of at least 45° C.

17. The method of claim 11, wherein etching is done for at least 45 seconds and the basic solution is heated to a temperature greater than 50° C.

18. The method of claim 11, wherein etching is done for at least 50 seconds and the basic solution is heated to a temperature greater than 55° C.

19. The method of claim 11, wherein etching is done for at least 55 seconds and the basic solution is heated to a temperature greater than 55° C.

20. The method of claim 11, wherein etching is done for at least 60 seconds and the basic solution is heated to a temperature greater than 55° C.
